(19) United States
(12) Patent Application Publication
(10) Pub. No.: US 2024/0170295 A1
(43) Pub. Date: May 23, 2024

(54) SEMICONDUCTOR STRUCTURE BONDING METHOD, BONDING EQUIPMENT, MEMORY, MEMORY SYSTEM

(71) Applicant: YANGTZE MEMORY TECHNOLOGIES CO., LTD., Wuhan (CN)

(72) Inventors: Guoliang Chen, Wuhan (CN); Mengyong Liu, Wuhan (CN); Yang Liu, Wuhan (CN); Junqing He, Wuhan (CN)

(21) Appl. No.: 18/090,955

(22) Filed: Dec. 29, 2022

(30) Foreign Application Priority Data
Nov. 18, 2022 (CN) 202211447354.1

(51) Int. Cl. H01L 21/3065; H01J 37/32; H01L 21/477; H01L 21/67

(52) U.S. Cl. CPC H01L 21/3065; H01J 37/32449; H01L 21/477; H01L 21/67023

(57) ABSTRACT

A semiconductor structure includes a first semiconductor structure and a second semiconductor structure. The method of bonding a semiconductor structure includes performing a surface treatment on a first surface of the first semiconductor structure and a second surface of the second semiconductor structure based on a first gas and a second gas. The first gas excites at least one of the first surface or the second surface to generate a free radical. The second gas is excited to generate a plasma gas. A free negative ion in the plasma gas is combined with the free radical. The method also includes performing a face-to-face bonding on the first surface and the second surface.

### CROSS-REFERENCE TO RELATED APPLICATIONS

This application claims the benefit of priority to Chinese Application No. 202211447354.1, filed on Nov. 18, 2022, which is incorporated herein by reference in its entirety.

### TECHNICAL FIELD

The present disclosure relates to the field of semiconductor technology, more specifically, to a method of bonding semiconductor structures, a bonding equipment, a memory, and a memory system.

### BACKGROUND

In the field of integrated circuit design and manufacturing, with the continuous improvement of semiconductor manufacturing technology, the process feature size is getting smaller and smaller, and the integration of integrated circuits is getting higher and higher. At the same time, as the process feature size of the semiconductor structure in the integrated circuit is shrinking, the difficulty of the forming process of the semiconductor structure is increasing, wherein in the forming process, the bonding process of the semiconductor structure has an important impact on the final formed semiconductor structure.

In the semiconductor forming process, it is often necessary to bond different semiconductor structures together to increase the number of devices per unit area. The bonding process of a semiconductor structure may be, for example, to tightly combine two semiconductor structures to be bonded by physical and chemical actions. After the two semiconductor structures to be bonded are bonded, the atoms at the bonding interface are integrated by van der Waals force, molecular force, and even atomic force under the action of external force, and the bonding interface is made to reach a specific bonding strength. It can be seen that bonding strength is one of the important factors affecting the bonding effect.

### SUMMARY

The present disclosure provides a method of bonding a semiconductor structure. The semiconductor structure includes a first semiconductor structure and a second semiconductor structure. The method includes performing a surface treatment on a first surface of the first semiconductor structure and a second surface of the second semiconductor structure based on a first gas and a second gas. The first gas excites at least one of the first surface or the second surface to generate a free radical. The second gas is excited to generate a plasma gas. A free negative ion in the plasma gas is combined with the free radical. The method also includes performing a face-to-face bonding on the first surface and the second surface.

In an embodiment, a material of at least one of the first surface or the second surface includes silicide, and the free radical includes an activated silicon ion; the first gas includes at least one of nitrogen, oxygen, and an inert gas; and the second gas includes water vapor, and the free negative ion includes a hydroxyl ion.

In an embodiment, the free negative ion combined with the free radical includes the activated silicon ion combined with the hydroxyl ion to generate a silanol radical.

In an embodiment, the first semiconductor structure and the second semiconductor structure are located in a chamber, the performing a surface treatment on a first surface of the first semiconductor structure and a second surface of the second semiconductor structure based on a first gas and a second gas includes injecting the first gas and the second gas into the chamber, wherein the first gas and the second gas are jointly injected into the chamber in a first time period.

In an embodiment, the method further includes monitoring and adjusting a concentration or a pressure intensity of at least one of the first gas, the second gas, or the free radical in the chamber.

In an embodiment, an intake amount of the first gas is adjusted in response to that the pressure intensity of the first gas in the chamber is monitored.

In an embodiment, the pressure intensity of the first gas in the chamber is in a range of 0.2 mbar-1.5 mbar.

In an embodiment, an intake amount of the second gas is adjusted in response to that the concentration of the second gas in the chamber is monitored.

In an embodiment, the concentration of the second gas in the chamber is in a range of 0.1 ppm-20 ppm.

In an embodiment, the method further includes cleaning the first surface and the second surface.

In an embodiment, the method further includes performing an annealing treatment on the bonded first surface and second surface.

In an embodiment, in the annealing treatment, the silanol radical is dehydrated and condensed to form a silicon-oxygen-silicon bond.

Another aspect of the present application provides a bonding equipment. The equipment includes a chamber configured to accommodate a structure to be bonded, a first gas, and a second gas. The chamber includes at least two gas inlets. The first gas and the second gas are injected into the chamber through the gas inlets. The first gas excites a surface of the structure to be bonded to generate a free radical, and the second gas is excited to generate a free negative ion. The equipment also includes a detection apparatus located in the chamber and configured to monitor a concentration or a pressure intensity of at least one of the first gas, the second gas, or the free radical in the chamber. The equipment further includes a control apparatus configured to adjust an intake amount of at least one of the first gas or an intake amount of the second gas according to the concentration or the pressure intensity monitored by the detection apparatus. The equipment further includes an execution apparatus configured to perform a face-to-face bonding on the structure to be bonded to form a bonded structure.

In an embodiment, the structure to be bonded includes a first semiconductor structure and a second semiconductor structure, wherein the first gas excites at least one of a first surface of the first semiconductor structure or a second surface of the second semiconductor structure to generate a free radical, the second gas is excited to generate a plasma gas, and a free negative ion in the plasma gas is combined with the free radical.

In an embodiment, the equipment further includes an adjusting apparatus configured to adjust an intake amount of the first gas according to the pressure intensity of the first gas monitored by the detection apparatus, so that the pressure intensity of the first gas in the chamber is in a range of 0.2 mbar-1.5 mbar.

In an embodiment, the equipment further includes an adjusting apparatus configured to adjust an intake amount of the second gas according to the concentration of the second gas monitored by the detection apparatus, so that the concentration of the second gas in the chamber is in a range of 0.1 ppm-20 ppm.

In an embodiment, the equipment further includes a cleaning apparatus configured to clean a surface of the structure to be bonded; and an annealing apparatus for performing an annealing treatment on the bonded structure.

Another aspect of the present application provides a three-dimensional memory including a semiconductor structure described above.

Another aspect of the present application provides a memory system that includes a controller and the three-dimensional memory described above, and the controller is coupled to the three-dimensional memory to control the three-dimensional memory to store data.

In one or more embodiments of the present disclosure, performing a surface treatment on a first surface of a first semiconductor structure and a second surface of a second semiconductor structure using a first gas and a second gas is conducive to the combination of a free radical generated by the first gas exciting at least one of the first surface or the second surface and a free negative ion in a plasma gas generated by the second gas being excited, so as to improve the number of free radicals combined with free negative ions, thus improve the bonding strength of the first surface and the second surface.

### BRIEF DESCRIPTION OF THE DRAWINGS

Other features, objects, and advantages of the present disclosure will become more apparent by reading the detailed description of the non-limiting embodiments made with reference to the following accompanying drawings, wherein:

FIG. 1 is a structure schematic diagram of a memory system according to an exemplary embodiment of the present disclosure;

FIG. 2 is a sectional schematic diagram of a memory according to an exemplary embodiment of the present disclosure;

FIG. 3 is a flowchart of a method of bonding semiconductor structure according to an exemplary embodiment of the present disclosure;

FIG. 4 is a schematic block diagram of a semiconductor structure according to an exemplary embodiment of the present disclosure;

FIG. 5 is a schematic diagram of performing a surface treatment on a first surface of a first semiconductor structure and a second surface of a second semiconductor structure according to an exemplary embodiment of the present disclosure;

FIG. 6 is a schematic diagram of cleaning a first surface and a second surface according to an exemplary embodiment of the present disclosure;

FIG. 7 is a schematic diagram of bonding a first surface and a second surface according to an exemplary embodiment of the present disclosure;

FIG. 8 is a schematic diagram of a first surface and a second surface in an annealing treatment according to an exemplary embodiment of the present disclosure; and

FIG. 9 is a schematic block diagram of a bonding equipment according to an exemplary embodiment of the present disclosure.

### DETAILED DESCRIPTION

In order to better understand the present disclosure, various aspects of the present disclosure will be described in more detail with reference to the accompanying drawings. It should be understood that these detailed descriptions are only a description of exemplary embodiments of the present disclosure and do not limit the scope of the present disclosure in any way.

It should be noted that in this specification, the expressions of the first, second, third, etc., are only used to distinguish one feature from another, and do not indicate any limitation on the features, especially do not indicate any successively sequence. Therefore, without departing from the teaching of the present disclosure, a first semiconductor structure discussed in the present disclosure may also be called a second semiconductor structure, and a first gas may also be called a second gas, and vice versa.

In the accompanying drawings, the thickness, size, and shape of the components have been slightly adjusted for ease of illustration. The accompanying drawings are examples only and are not drawn strictly to scale. As used herein, the terms “approximately,” “about,” and similar terms are used to express approximation rather than degree, and are intended to explain the inherent deviation in the measured or calculated value that will be recognized by those skilled in the art.

In addition, when describing that one part is “on top of” another part herein, the meaning of the terms such as “on,” “over” and “above” should be interpreted in the broadest way, so that “on” not only means “directly on something,” but also includes the meaning of “on something” with intermediate features or layers therebetween, and “over” or “above” does not absolutely mean to be on top based on the direction of gravity, nor does it mean “over something” or “above something,” but it can also include the meaning of “over something” or “above something” without intermediate features or layers therebetween (that is, directly on something).

It should also be understood that the expressions such as “include,” “included,” “have,” “contain” and/or “contained” are open rather than closed expressions in this specification, which indicate the existence of the stated features, elements and/or components, but do not exclude the existence of one or more other features, elements, components and/or combinations thereof. Further, when a statement such as “at least one of.” appears before the list of listed features, it modifies the entire list of features rather than just individual elements in the list. In addition, when describing the embodiments of the present disclosure, “may” is used to mean “one or more embodiments of the present disclosure.” Further, the term “exemplary” is intended to refer to an example or exemplary illustration.

The description is conducted with reference to the schematic diagrams of the exemplary embodiments herein. The exemplary embodiments disclosed herein should not be interpreted as being limited to the specific shapes and sizes shown but include various equivalent structures capable of achieving the same function, and deviations of shape and size resulting from, for example, manufacturing. The positions shown in the accompanying drawings are schematic in nature and are not intended to limit the positions of the various components.

Unless otherwise defined, all terms used herein (including technical terms and scientific terms) have the same meaning as those generally understood by those skilled in the art to which the disclosure belongs. Terms such as those defined in common dictionaries shall be interpreted as having the same meaning as their meaning in the context of the relevant field and will not be interpreted in an idealized or overly formal sense, unless explicitly so defined herein.

As used herein, the term “layer” refers to a material portion including a region having a height. The layer can be a region of homogenous or inhomogenous continuous structure, and its height is less than the height of the continuous structure. For example, a layer can be located between any pair of horizontal planes between, or at, a top surface and a bottom surface of the continuous structure. A layer can extend horizontally, vertically, and/or along a tapered surface. A layer can include multiple layers.

It should be noted that, when not conflicting with each other, the embodiments and features in the embodiments in the present disclosure can be combined with each other. In addition, unless explicitly defined or contradicted with the context, the specific steps contained in the method described in the present disclosure need not be limited to the recited sequence but can be executed in any sequence or in parallel. The present disclosure will be described in detail below with reference to the accompanying drawings and in combination with embodiments.

In addition, when “connect,” or “link” is used in the present disclosure, it may indicate that the corresponding parts are in direct contact or indirect contact, unless there are other explicit limitations, or it can be derived from the context.

FIG. 1 is a structure schematic diagram of a memory system 1 according to an embodiment of the present disclosure. As shown in FIG. 1, the memory system 1 may include a controller 3 and at least one three-dimensional memory 2, and the controller 3 is coupled to the three-dimensional memory 2 to control the three-dimensional memory 2 to store data. The memory system 1 can be integrated into various memory cards such as personal computer memory card International Association (PCMCIA or PC), compact flash (CF) card, smart media (SM) card, memory stick, multimedia card (MMC), secure digital memory card (SD), universal flash storage (UFS) and solid-state drive (SSD), and so on.

The controller 3 may be configured to operate in a low duty cycle environment, for example, an SD card, a CF card, a universal serial bus (USB) flash drive, or other media used in an electronic equipment, such as a personal calculator, a digital camera, a mobile phone, etc.

In addition, the controller 3 may also be configured to operate in a high duty cycle environment SSD or eMMC, and SSD or eMMC is used for a data memory of a mobile equipment such as a smart phone, a tablet, a laptop, and an enterprise memory array.

As an option, the controller 3 may also be configured to manage the data stored in the three-dimensional memory 2 and communicate with an external equipment according to a specific communication protocol. Communication protocols may include at least one of USB protocol, MMC protocol, peripheral component interconnect (PCI) protocol, peripheral component interconnect express (PCI-E) protocol, advanced technology attachment (ATA) protocol, serial ATA protocol, parallel ATA protocol, small computer system interface (SCSI) protocol, enhanced small drive interface (ESDI) protocol, integrated drive electronics (IDE) protocol and FireWire protocol.

In addition, the controller 3 may also be configured to control operations of the three-dimensional memory 2, for example, reading, erasing, and programming operations. In some embodiments, the controller 3 may also be configured to manage various functions related to the data stored or to be stored in the three-dimensional memory 2, including at least one of bad block management, garbage collection, logical to physical address translation, and loss balancing. In some embodiments, the controller 3 may also be configured to process error correction codes related to data read from or written to the three-dimensional memory 2. In addition, the controller 3 may perform any other suitable function, for example, formatting the three-dimensional memory 2.

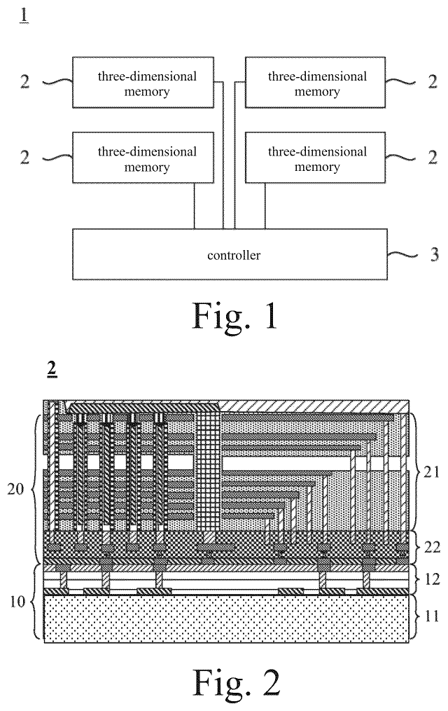

FIG. 2 is a section schematic diagram of a memory 2 according to an embodiment of the present disclosure. As shown in FIG. 2, the three-dimensional memory 2 may include a peripheral device 10 (such as a first semiconductor structure) and a memory array device 20 (such as a second semiconductor structure). The peripheral device 10 may be electrically connected with the memory array device 20 to realize the functional support of the peripheral device 10 to the memory array device 20, for example, reading, writing, and erasing the data of the memory unit.

The memory array device 20 may include a memory unit string array 21 and an array interconnection layer 22. The array interconnection layer 22 is arranged on the side of the memory unit string array 21 close to the peripheral device 10, and the memory unit string array 21 may be electrically connected with the array interconnection layer 22.

The peripheral device 10 may include a peripheral circuit 11 and a peripheral interconnection layer 12. The peripheral circuit 11 may be used to control and detect the switching state of each memory unit string array 21 to realize data storage and reading. As an option, the peripheral circuit 11 may include, for example, a page buffer, a decoder, a readout amplifier, a driver, a charge pump, a current or voltage reference, and the like. The peripheral interconnection layer 12 may be arranged on the side of the peripheral circuit 11 close to the memory array device 20, and the peripheral circuit 11 may be electrically connected with the peripheral interconnection layer 12.

For example, in the three-dimensional memory 2, the peripheral device 10 and the memory array device 20 may be bonded to realize an electrical connection between the peripheral device 10 and the memory array device 20. At this time, the peripheral device 10 may be regarded as the first semiconductor structure referred to below, and the memory array device 20 may be regarded as the second semiconductor structure referred to below;

alternatively, the memory array device 20 may be regarded as a first semiconductor structure referred to below, and the peripheral device 10 may be regarded as a second semiconductor structure referred to below.

For example, the electrical connection between the peripheral device 10 and the memory array device 20 may be realized by realizing the electrical connection between the array interconnection layer 22 and the peripheral interconnection layer 12. That is, the bonding between the peripheral device 10 and the memory array device 20 may be realized by bonding the peripheral interconnection layer 12 and the array interconnection layer 22. At this time, the surface of the peripheral interconnection layer 12 close to the array interconnection layer 22 may be regarded as the first surface of the first semiconductor structure referred to below, and the surface of the array interconnection layer 22 close to the peripheral interconnection layer 12 may be regarded as the second surface of the second semiconductor structure referred to below; alternatively, the surface of the array interconnection layer 22 close to the peripheral interconnection layer 12 may be regarded as the first surface of the first semiconductor structure referred to below, and the surface of the peripheral interconnection layer 12 close to the array interconnection layer 22 may be regarded as the second surface of the second semiconductor structure referred to below.

It should be understood that the first semiconductor structure, the second semiconductor structure, the first surface, and the second surface listed here are only examples and do not exhaustively explain all possible structures of the first semiconductor structure and the second semiconductor structure. In the following description, the first surface of the first semiconductor structure can be exemplarily understood as the surface of the array interconnection layer 22 close to the peripheral interconnection layer 12, and the second surface of the second semiconductor structure can be exemplarily understood as the surface of the peripheral interconnection layer 12 close to the array interconnection layer 22. The method 1000 of bonding semiconductor structures will be described in detail below. In addition, the application scenarios of method 1000 of bonding the semiconductor structure listed in the present disclosure are only examples, and do not exhaustively explain all possible application scenarios of method 1000 of bonding the semiconductor structure. In practical applications, the method 1000 of bonding the semiconductor structure provided in the present disclosure may be applied to any suitable scenario.

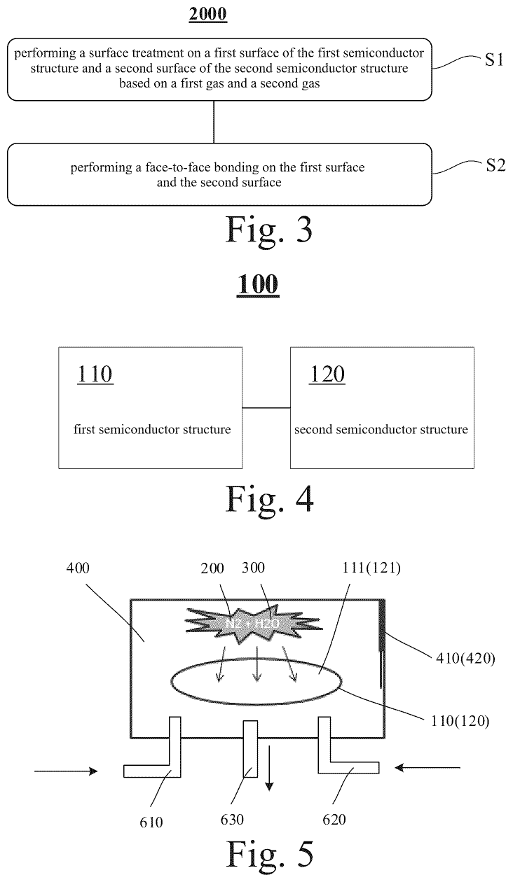

FIG. 3 is a flowchart of method 1000 of bonding a semiconductor structure according to an exemplary embodiment of the present disclosure.

As shown in FIG. 3, the method 1000 of bonding the semiconductor structure may include: S1, performing a surface treatment on the first surface of the first semiconductor structure and the second surface of the second semiconductor structure based on the first gas and the second gas, wherein the first gas excites the first surface and/or the second surface to generate a free radical; and the second gas is excited to generate a plasma gas, and the free negative ion in the plasma gas is combined with a free radical; and S2, performing a face-to-face bonding on the first surface and the second surface. Steps S1 and S2 will be described in detail below.

In the exemplary embodiment of the present disclosure, as shown in FIG. 4, the semiconductor structure 100 may include a first semiconductor structure 110 and a second semiconductor structure 120. For example, the first semiconductor structure 110 can be an array interconnection layer, and the second semiconductor structure 120 can be a peripheral interconnection layer.

In the exemplary embodiment of the present disclosure, as shown in FIG. 5, a surface treatment may be performed on the first surface 111 of the first semiconductor structure 110 and the second surface 121 of the second semiconductor structure 120 based on the first gas 200 and the second gas 300. For example, the first semiconductor structure 110 and the second semiconductor structure 120 may be located in the chamber 400. For example, a surface treatment may be performed on the first surface 111 and the second surface 121 by simultaneously injecting the first gas 200 and the second gas 300 into the chamber 400 during the first time period. For example, the chamber 400 can be a plasma activation treatment chamber, and a plasma activation treatment process may be performed within the chamber 400. In the present disclosure, through the plasma activation treatment process, the first gas 200 may be used to excite the first surface 111 and/or the second surface 121 to generate a free radical, such as an activated silicon ion Si+. At the same time, the second gas 300 may be excited to generate a plasma gas, such as a plasma gas generated after water vapor being ionized. The free negative ion in the plasma gas may combine with a free radical to generate, such as a silanol radical Si-Oh.

In the present disclosure, by simultaneously injecting the first gas 200 and the second gas 300 in the first time period, it is possible to realize the rapid combination of the generated free radicals and free negative ions, so as to increase the combined number of free radicals and free negative ions, thereby improving the bonding strength of the first surface 111 and the second surface 121.

Due to the poor performance stability of the generated free radicals and free negative ions, it is very easy for them to return to the initial states. For example, it is very easy for the free radicals (activated silicon ions Si+) to combine with the free particles such as (O+) on the first surface 111 and/or the second surface 121 to generate substances when not excited, such as silicon oxide SiO₂, and it is very easy for the free negative ions (such as OH−) to combine with the free positive ions (such as H+) to generate plasma gases such as H₂O. Therefore, by simultaneously injecting the first gas 200 and the second gas 300 in the first time period, the present disclosure can achieve the rapid combination of the generated free radicals and free negative ions, so as to avoid the free radicals and free negative ions returning to the initial states respectively. In other words, in the present disclosure, in the course of generating free radicals and free negative ions, the previously generated free radicals and free negative ions have been combined, thereby improving the efficiency and number of the combination of free radicals and free negative ions.

For example, a material of the first surface 111 and/or the second surface 121 may include silicide. For example, a material of the first surface 111 and/or the second surface 121 may include metallic silicide or non-metallic silicide. The free radical may include an activated silicon ion Si+. In the present disclosure, the first gas 200 may be used to perform a surface activation treatment (i.e., a plasma activation treatment) on the first surface 111 and the second surface 121 through the plasma activation treatment process to excite the first surface 111 and/or the second surface 121 to generate free radicals such as activated silicon ions Si+. In other words, in the plasma activation treatment process, the first gas 200 can break the silicon-silicon bond, silicon-oxygen bond, silicon-metal bond, etc. on the first surface 111 and/or the second surface 121. For example, the first gas 200 can break the bonds of silicon oxide molecules formed by natural or thermal oxidation on the first surface 111 and/or the second surface 121.

For example, the first gas 200 may include at least one of nitrogen, oxygen, and an inert gas. For example, as shown in FIG. 5, the first gas 200 can be nitrogen. In the present disclosure, when a material of the first surface 111 and/or the second surface 121 includes a metal silicide, the first gas 200 may include at least one of nitrogen and an inert gas, that is, at this time, the first gas 200 does not include oxygen to prevent the metal oxidation reaction between oxygen and metal silicide. In addition, considering the low price of nitrogen, nitrogen may be used as the first gas 200 to reduce costs.

For example, while a surface activation treatment is performed on the first surface 111 and the second surface 121 using the first gas 200, the second gas 300 may be excited to generate a plasma gas. At this time, the free negative ions in the plasma gas may combine with free radicals. For example, the second gas 300 may include water vapor, and the free negative ion may include a hydroxyl ion OH−. For example, water vapor may be ionized to generate the hydroxyl ion OH− through the plasma activation treatment process. The hydroxyl ions OH− may be bombarded onto the first surface 111 and the second surface 121 and combined with the activated silicon ions Si+ on the first surface 111 and the second surface 121 to generate silanol radicals Si—OH.

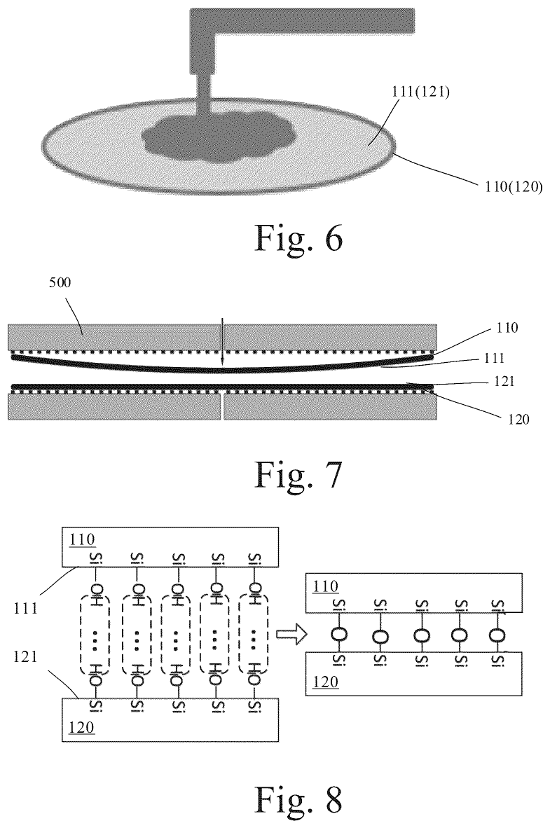

In the exemplary embodiment of the present disclosure, as shown in FIG. 6, the first surface 111 and the second surface 121 may be cleaned. For example, after the surface treatment is performed on the first surface 111 and the second surface 121, the first surface 111 and the second surface 121 may be washed with liquid water or deionized water so that more hydroxyl radicals (free hydroxyl radicals from liquid water or deionized water) exist on the first surface 111 and the second surface 121. Hydroxyl radicals may combine with the activated silicon ions Si+ on the first surface 111 and the second surface 121 to generate silanol radicals Si—OH, further increasing the number of silanol radicals Si—OH on the first surface 111 and the second surface 121.

In the exemplary embodiment of the present disclosure, as shown in FIG. 7, the first surface 111 and the second surface 121 may be bonded face-to-face. For example, after cleaning the first surface 111 and the second surface 121, the first surface 111 and the second surface 121 may be bonded face-to-face so that the first surface 111 and the second surface 121 are in physical contact. For example, the first semiconductor structure 110 may be flipped up and down by the bonding clip 500 so that the first surface 111 of the first semiconductor structure 110 can remain facing the second surface 121 of the second semiconductor structure 120 in a face-to-face manner. Of course, a mechanical locking mechanism and/or vacuum pumping can also be used to hold the first surface 111 and the second surface 121 in a face-to-face manner after alignment. For example, in the bonding process, pressure may be applied to the first semiconductor structure 110 and the second semiconductor structure 120 through the bonding clip 500 to make the first surface 111 physically contact the second surface 121. For example, during the course of bonding process, van der Waals bonds and hydrogen bonds of hydroxyl radicals may be formed between the first surface 111 and the second surface 121 opposite to each other.

In the exemplary embodiment of the present disclosure, an annealing treatment may be performed on the bonded first surface 111 and second surface 121. That is, a heat treatment may be performed on the bonded first semiconductor structure 110 and second semiconductor structure 120. For example, the heat treatment process may be applied to the first semiconductor structure 110 and the second semiconductor structure 120 through the heating element in the bonding clip 500. As shown in FIG. 8, during the heat treatment, the silanol radicals Si—OH on the first surface 111 and the second surface 121 may be dehydrated and condensed to form a silicon-oxygen-silicon bond (Si—O—Si bond), so that the first surface 111 and the second surface 121 may be bonded together, that is, the first semiconductor structure 110 and the second semiconductor structure 120 may be bonded together. The dehydration condensation reaction formula may be Si—OH+HO-Si→SiO₂+H₂O.

In the exemplary embodiment of the present disclosure, as shown in FIG. 5, during the injection of the first gas 200 and the second gas 300 into the chamber 400, the concentration or pressure intensity of at least one of the first gas 200, the second gas 300 and the free radicals in the chamber 400 may be monitored and adjusted. For example, the pressure intensity of the first gas 200 and/or the concentration of the second gas 300 may be monitored, and the intake amount of the first gas 200 and/or the second gas 300 may be adjusted based on the monitored results. For example, a pressure intensity sensor 410 and/or a concentration sensor 420 may be provided on the inner wall of the chamber 400. The pressure intensity sensor 410 may be used to monitor the pressure intensity of the first gas 200 in the chamber 400. The concentration sensor 420 may be used to monitor the concentration of the second gas 300 in the chamber 400.

For example, the pressure intensity sensor 410 may monitor the pressure intensity of the first gas 200 in the chamber 400 in real time and transmit the monitored pressure intensity value P to the controller in the form of an electrical signal (not shown in FIG. 5). The controller may compare the received pressure intensity value P with the first pressure intensity threshold P1 and the second pressure intensity threshold P2 respectively, wherein the first pressure intensity threshold P1 is less than the second pressure intensity threshold P2. When the pressure intensity value P is lower than the first pressure intensity threshold P1, that is, P<P1, the controller will adjust the intake amount of the first gas 200 to increase the pressure intensity of the first gas 200 in the chamber 400. In addition, when the pressure intensity value P is higher than the second pressure intensity threshold P2, that is, P>P2, the controller will adjust the intake amount of the first gas 200 to reduce the pressure intensity of the first gas 200 in the chamber 400. For example, the first gas 200 may enter the chamber 400 through a first gas inlet 610. Through the interaction between the pressure intensity sensor 410 and the controller, the pressure intensity value of the first gas 200 in the chamber 400 may be maintained in the range of P1˜P2. For example, the first pressure intensity threshold P1 may be greater than or equal to 0.2 mbar, and the second pressure intensity threshold P2 may be less than or equal to 1.5 mbar, that is, the pressure intensity value P of the first gas 200 in the chamber 400 may be maintained in the range of 0.2 mbar to 1.5 mbar. For example, the pressure intensity value P of the first gas 200 in the chamber 400 may be maintained in the range of 0.7 MPa to 0.9 MPa.

For example, the concentration sensor 420 may monitor the concentration of the second gas 300 in the chamber 400 in real time and transmit the monitored concentration value T to the controller in the form of an electrical signal (not shown in FIG. 5). The controller may compare the received concentration value T with the first concentration threshold T1 and the second concentration threshold T2 respectively, wherein the first concentration threshold T1 is less than the second concentration threshold T2. When the concentration value T is lower than the first concentration threshold T1, that is, T<T1, the controller will adjust the intake amount of the second gas 300 to increase the concentration of the second gas 300 in the chamber 400. In addition, when the concentration value T is higher than the second concentration threshold T2, that is, T>T2, the controller will adjust the intake amount of the second gas 300 to reduce the concentration of the second gas 300 in the chamber 400. For example, the second gas 300 may enter the chamber 400 through a second gas inlet 620. Through the interaction between the concentration sensor 420 and the controller, the concentration value of the second gas 300 in the chamber 400 may be maintained in the range of T1˜T2. For example, the first concentration threshold T1 may be greater than or equal to 0.1 ppm, and the second concentration threshold T2 may be less than or equal to 20 ppm, that is, the concentration value T of the second gas 300 in the chamber 400 may be maintained in the range of 0.1 ppm to 20 ppm. For example, the concentration value T of the second gas 300 in the chamber 400 may be maintained in the range of 0.25 ppm to 15 ppm.

That, as listed in the present disclosure, the pressure intensity sensor 410 is used to monitor the pressure intensity of the first gas 200, and the concentration sensor 420 is used to monitor the concentration of the second gas 300, is only an example, and not a specific limitation to the pressure intensity sensor 410 and the concentration sensor 420. It is understood that the pressure intensity sensor 410 may also be used to monitor the pressure intensity of the second gas 300, and the concentration sensor 420 may also be used to monitor the concentration of the first gas 200, which is not explicitly defined in the present disclosure. In practical applications, the use of pressure intensity sensor 410 and/or concentration sensor 420 may be reasonably selected according to the actual situation.

During the course of performing a surface treatment on the first surface 111 and the second surface 121, after the first gas 200 and the second gas 300 are injected into the chamber 400, various free particles such as H+ and OH− will also combine, for example, combining to form such as water vapor. Based on this, in the present disclosure, the generated gas may be discharged through the air outlet 630. It is understood that, during the surface treatment course, it is a circulating flow course to fill the chamber 400 with gas through the first gas inlet 610 and the second gas inlet 620, and to discharge the gas through the air outlet 630.

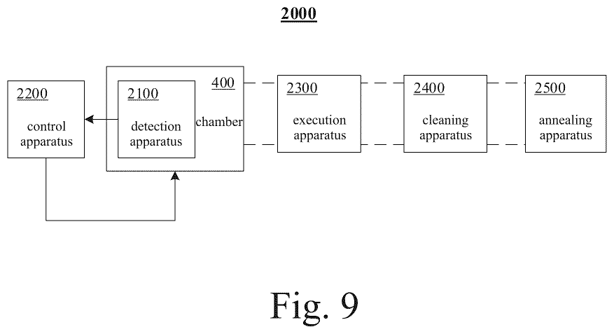

On the other hand, the present disclosure provides a bonding equipment 2000. As shown in FIG. 9, the equipment 2000 may include a chamber 400, a detection apparatus 2100, a control apparatus 2200, and an execution apparatus 2300. The equipment 2000 may be used to perform a bonding treatment on a structure to be bonded, such as a semiconductor structure 100 (FIG. 4).

The chamber 400 may be configured to accommodate structures to be bonded, such as the semiconductor structure 100, the first gas 200, and the second gas 300 (FIG. 5). The chamber 400 may include at least two gas inlets, and the first gas 200 and the second gas 300 may be injected into the chamber 400 through the gas inlets. The first gas 200 may be used to excite the first surface 111 and/or the second surface 121 to generate free radicals. The second gas 300 may be excited to generate free negative ions.

The detection apparatus 2100 may be located in the chamber 400 and configured to monitor the concentration or pressure intensity of at least one of the first gas 200, the second gas 300, and the free radicals in the chamber 400. The control apparatus 2200 may be configured to adjust the intake amount of the first gas 200 and/or the intake amount of the second gas 300 according to the concentration or pressure intensity monitored by the detection apparatus 2100. The execution apparatus 2300 may be configured to perform a face-to-face bonding on a structure to be bonded, such as the semiconductor structure 100, to form a bonded structure.

For example, as shown in FIG. 4, the structure to be bonded, such as the first semiconductor structure 100, may include a first semiconductor structure 110 and a second semiconductor structure 120. As shown in FIG. 5, the chamber 400 may include a first gas inlet 610 and a second gas inlet 620. The first gas 200 may be injected into the chamber 400 through the first gas inlet 610, and the second gas 300 may be injected into the chamber 400 through the second gas inlet 620. For example, a surface treatment may be performed on the first surface 111 of the first semiconductor structure 110 and the second surface 121 of the second semiconductor structure 120 by simultaneously injecting the first gas 200 and the second gas 300 into the chamber 400 during the first time period. For example, the chamber 400 can be a plasma activation treatment chamber, and a plasma activation treatment process may be performed in the chamber 400. In the present disclosure, through the plasma activation treatment process, the first surface 111 and/or the second surface 121 may be excited with the first gas 200 to generate free radicals. At the same time, the second gas 300 may be excited to generate a plasma gas, such as being ionized to generate a plasma gas. The free negative ions in the plasma gas may combine with free radicals.

In the present disclosure, by simultaneously injecting the first gas 200 and the second gas 300 in the first time period, it can be achieved that the generated free radicals can be rapidly combined with free negative ions, so as to increase the number of free radicals combined with free negative ions, and further improve the bonding strength of the first surface and the second surface.

Due to the poor performance stability of the generated free radicals and free negative ions, it is very easy for them to return to the initial states. For example, it is very easy for the free radicals (activated silicon ions Si+) to combine with the free particles (such as O+) on the first surface 111 and/or the second surface 121 to generate substances when not excited such as silicon oxide SiO₂, and it is very easy for the free negative ions (such as OH−) to combine with the free positive ions (such as H+) to generate plasma gases such as H₂O. Therefore, by simultaneously injecting the first gas 200 and the second gas 300 in the first time period, the present disclosure can rapidly combine the generated free radicals and free negative ions, so as to avoid the free radicals and free negative ions returning to the initial states, respectively. In other words, in the present disclosure, in the course of generating free radicals and free negative ions, the previously generated free radicals and free negative ions have been combined, thereby improving the efficiency and number of the combination of free radicals and free negative ions.

For example, the detection apparatus 2100 may include a pressure intensity sensor 410 and/or a concentration sensor 420 (FIG. 5). During the injection of the first gas 200 and the second gas 300 into the chamber 400, the concentration or pressure intensity of at least one of the first gas 200, the second gas 300 and the free radicals in the chamber 400 may be monitored by the detection apparatus 2100. For example, the pressure intensity of the first gas 200 in the chamber 400 may be monitored by the pressure intensity sensor 410. The concentration of the second gas 300 in the chamber 400 is monitored by the concentration sensor 420.

For example, the pressure intensity of the first gas 200 and/or the concentration of the second gas 300 may be monitored by the detection apparatus 2100. The control apparatus 2200 may adjust the intake amount of the first gas 200 and/or the second gas 300 based on the monitored results. For example, the control apparatus 2200 may include the controller mentioned above.

For example, the pressure intensity sensor 410 may monitor the pressure intensity of the first gas 200 in the chamber 400 in real time and transmit the monitored pressure intensity value P to the control apparatus 2200 in the form of an electrical signal. The control apparatus 2200 may compare the received pressure intensity value P with the first pressure intensity threshold P1 and the second pressure intensity threshold P2, respectively, wherein the first pressure intensity threshold P1 is less than the second pressure intensity threshold P2. When the pressure intensity value P is lower than the first pressure intensity threshold P1, that is, P<P1, the control apparatus 2200 will adjust the intake amount of the first gas 200 to increase the pressure intensity of the first gas 200 in the chamber 400. In addition, when the pressure intensity value P is higher than the second pressure intensity threshold P2, that is, P>P2, the control apparatus 2200 will adjust the intake amount of the first gas 200 to reduce the pressure intensity of the first gas 200 in the chamber 400. For example, the first gas 200 may enter the chamber 400 through the first gas inlet 610. Through the interaction between the pressure intensity sensor 410 and the control apparatus 2200, the pressure intensity value of the first gas 200 in the chamber 400 may be maintained in the range of P1˜P2. For example, the first pressure intensity threshold P1 may be greater than or equal to 0.2 mbar, and the second pressure intensity threshold P2 may be less than or equal to 1.5 mbar, that is, the pressure intensity value P of the first gas 200 in the chamber 400 may be maintained in the range of 0.2 mbar to 1.5 mbar. For example, the pressure intensity value P of the first gas 200 in the chamber 400 may be maintained in the range of 0.7 MPa to 0.9 MPa.

For example, the concentration sensor 420 may monitor the concentration of the second gas 300 in the chamber 400 in real time and transmit the monitored concentration value T to the controller in the form of an electrical signal. The control apparatus 2200 may compare the received concentration value T with the first concentration threshold T1 and the second concentration threshold T2 respectively, wherein the first concentration threshold T1 is less than the second concentration threshold T2. When the concentration value T is lower than the first concentration threshold T1, i.e., T<T1, the control apparatus 2200 will adjust the intake amount of the second gas 300 to increase the concentration of the second gas 300 in the chamber 400. In addition, when the concentration value T is higher than the second concentration threshold T2, that is, T>T2, the control apparatus 2200 will adjust the intake amount of the second gas 300 to reduce the concentration of the second gas 300 in the chamber 400. For example, the second gas 300 may enter the chamber 400 through the second gas inlet 620. Through the interaction between the concentration sensor 420 and the control apparatus 2200, the concentration value of the second gas 300 in the chamber 400 may be maintained in the range of T1˜T2. For example, the first concentration threshold T1 may be greater than or equal to 0.1 ppm, and the second concentration threshold T2 may be less than or equal to 20 ppm, that is, the concentration value T of the second gas 300 in the chamber 400 may be maintained in the range of 0.1 ppm-20 ppm. For example, the concentration value T of the second gas 300 in the chamber 400 may be maintained in the range of 0.25 ppm to 15 ppm.

In the exemplary embodiment of the present disclosure, the bonding equipment 2000 may also include a cleaning apparatus 2400. The cleaning apparatus 2400 may be used to clean the surface of the structure to be bonded, such as the semiconductor structure 100. For example, the cleaning apparatus 2400 may be used to clean the first surface 111 and the second surface 121 (FIG. 6). For example, after surface treatment is performed on the first surface 111 and the second surface 121, the first surface 111 and the second surface 121 may be washed with liquid water or deionized water so that more hydroxyl radicals (free hydroxyl radicals from liquid water or deionized water) exist on the first surface 111 and the second surface 121. Hydroxyl radicals may combine with the activated silicon ions Si+ on the first surface 111 and the second surface 121 to generate silanol radicals Si—OH, further increasing the number of silanol radicals Si—OH on the first surface 111 and the second surface 121.

In the exemplary embodiment of the present disclosure, after cleaning the first surface 111 and the second surface 121, the first surface 111 and the second surface 121 may be bonded face-to-face by execution apparatus 2300 to form a bonded structure. The execution apparatus 2300 may include a bonding clip 500 (FIG. 7). For example, the first semiconductor structure 110 may be flipped up and down by the bonding clip 500 so that the first surface 111 of the first semiconductor structure 110 can remain facing the second surface 121 of the second semiconductor structure 120 in a face-to-face manner. Of course, a mechanical locking mechanism and/or vacuum pumping can also be used to maintain the first surface 111 and the second surface 121 in a face-to-face manner after alignment. For example, in the bonding process, an electric field may be applied to the first semiconductor structure 110 and the second semiconductor structure 120 through the electrode in the bonding clip 500. In other words, pressure may be applied to the first semiconductor structure 110 and the second semiconductor structure 120 through the bonding clip 500 to make the first surface 111 physically contact the second surface 121. For example, during the course of the bonding process, van der Waals bonds and hydrogen bonds of hydroxyl radicals may be formed between the first surface 111 and the second surface 121 opposite to each other.

In the exemplary embodiment of the present disclosure, the bonding equipment 2000 may further include an annealing apparatus 2500. The annealing apparatus 2500 may be used to perform an annealing treatment on the bonded structure. For example, an annealing treatment may be performed on the bonded first surface 111 and second surface 121. That is, a heat treatment process may be performed on the bonded first semiconductor structure 110 and second semiconductor structure 120. For example, a heat treatment process may be applied to the first semiconductor structure 110 and the second semiconductor structure 120 through the heating element in the bonding clip 500. As shown in FIG. 8, during the heat treatment, the silanol radicals Si—OH on the first surface 111 and the second surface 121 may be dehydrated and condensed to form a silicon-oxygen-silicon bond (Si—O—Si bond), so that the first surface 111 and the second surface 121 may be bonded together, that is, the first semiconductor structure 110 and the second semiconductor structure 120 are bonded together. The dehydration condensation reaction formula may be Si—OH+HO-Si→SiO₂+H₂O.

Since the content and structure involved in the above description of the method 1000 of bonding the semiconductor structure may be fully or partially applicable to the bonding equipment 2000 described here, the related or similar content will not be repeated here.

Although an exemplary preparation method and structure of a semiconductor structure are described herein, it is understood that one or more features can be omitted, replaced, or added from the structure of the semiconductor structure. In addition, the various illustrated layers and their materials are only exemplary.

The above description is only a description of the preferred embodiment of the present disclosure and the applied technical principles. Those skilled in the art should understand that the scope of the present disclosure involved in the present disclosure is not limited to the technical solutions formed by the specific combination of the above technical features, but also covers other technical solutions formed by the arbitrary combination of the above technical features or their equivalent features without departing from the inventive concept, for example, the technical solutions formed by replacing the above features with (but not limited to) the technical features with similar functions disclosed in the present disclosure with each other.

What is claimed is:

1. A method of bonding a semiconductor structure comprising a first semiconductor structure and a second semiconductor structure, the method comprising:
performing a surface treatment on a first surface of the first semiconductor structure and a second surface of the second semiconductor structure based on a first gas and a second gas, wherein the first gas excites at least one of the first surface or the second surface to generate a free radical, the second gas is excited to generate a plasma gas, and a free negative ion in the plasma gas is combined with the free radical; and
performing a face-to-face bonding on the first surface and the second surface.

2. The method according to claim 1, wherein
a material of the at least one of the first surface or the second surface includes silicide, and the free radical includes an activated silicon ion;
the first gas includes at least one of nitrogen, oxygen, and an inert gas; and
the second gas includes water vapor, and the free negative ion includes a hydroxyl ion.

3. The method according to claim 2, wherein the free negative ion combined with the free radical includes that the activated silicon ion combined with the hydroxyl ion to generate a silanol radical.

4. The method according to claim 1, wherein
the first semiconductor structure and the second semiconductor structure are located in a chamber; and
the performing a surface treatment on a first surface of the first semiconductor structure and a second surface of the second semiconductor structure based on a first gas and a second gas includes injecting the first gas and the second gas into the chamber, the first gas and the second gas being jointly injected into the chamber in a first time period.

5. The method according to claim 4, further comprising:
monitoring and adjusting a concentration or a pressure intensity of at least one of the first gas, the second gas, or the free radical in the chamber.

6. The method according to claim 5, wherein an intake amount of the first gas is adjusted in response to that the pressure intensity of the first gas in the chamber is monitored.

7. The method according to claim 5, wherein the pressure intensity of the first gas in the chamber is in a range of 0.2 mbar-1.5 mbar.

8. The method according to claim 5, wherein an intake amount of the second gas is adjusted in response to that the concentration of the second gas in the chamber is monitored.

9. The method according to claim 5, wherein the concentration of the second gas in the chamber is in a range of 0.1 ppm-20 ppm.

10. The method according to claim 1, further comprising:
cleaning the first surface and the second surface.

11. The method according to claim 3, further comprising:
performing an annealing treatment on the bonded first surface and second surface.

12. The method according to claim 11, wherein, in the annealing treatment, the silanol radical is dehydrated and condensed to form a silicon-oxygen-silicon bond.

13. A bonding equipment, comprising:
a chamber configured to accommodate a structure to be bonded, a first gas, and a second gas, and comprising at least two gas inlets, the first gas and the second gas being injected into the chamber through the gas inlets, wherein the first gas excites a surface of the structure to be bonded to generate a free radical, and the second gas is excited to generate a free negative ion;
a detection apparatus located in the chamber and configured to monitor a concentration or a pressure intensity of at least one of the first gas, the second gas, or the free radical in the chamber;
a control apparatus configured to adjust an intake amount of at least one of the first gas or an intake amount of the second gas according to the concentration or the pressure intensity monitored by the detection apparatus; and
an execution apparatus configured to perform a face-to-face bonding on the structure to be bonded to form a bonded structure.

14. The equipment according to claim 13, wherein the structure to be bonded includes a first semiconductor structure and a second semiconductor structure;
the first gas excites at least one of a first surface of the first semiconductor structure or a second surface of the second semiconductor structure to generate a free radical;
the second gas is excited to generate a plasma gas; and
a free negative ion in the plasma gas is combined with the free radical.

15. The equipment according to claim 14, further comprising an adjusting apparatus configured to adjust an intake amount of the first gas according to the pressure intensity of the first gas monitored by the detection apparatus, so that the pressure intensity of the first gas in the chamber is in a range of 0.2 mbar-1.5 mbar.

16. The equipment according to claim 14, further comprising an adjusting apparatus configured to adjust an intake amount of the second gas according to the concentration of the second gas monitored by the detection apparatus, so that the concentration of the second gas in the chamber is in a range of 0.1 ppm-20 ppm.

17. The equipment according to claim 13, further comprising:
a cleaning apparatus configured to clean a surface of the structure to be bonded; and
an annealing apparatus configured to perform an annealing treatment on the bonded structure.
